(19) United States
(12) Patent Application Publication
(10) Pub. No.: US 2025/0318076 A1
(43) Pub. Date: Oct. 9, 2025

(54) CURRENT BUSBAR SYSTEM

(71) Applicant: Delta Electronics, Inc., Taoyuan City (TW)

(72) Inventors: Ming Tang YANG, Taoyuan City (TW); Chin LIEN, Taoyuan City (TW); Ren-Chun CHANG, Taoyuan City (TW); Zih-Yang FANG, Taoyuan City (TW); Shao-Li CHIU, Taoyuan City (TW); Chih-Chiang CHAN, Taoyuan City (TW)

(21) Appl. No.: 19/069,859

(22) Filed: Mar. 4, 2025

Related U.S. Application Data
(60) Provisional application No. 63/631,630, filed on Apr. 9, 2024.

(30) Foreign Application Priority Data
Jun. 18, 2024 (TW) 113122437

(51) Int. Cl. H05K 7/20; H02G 5/10

(52) U.S. Cl. CPC H05K 7/20272; H02G 5/10; H05K 7/20281

(57) ABSTRACT

A current busbar system is provided. The current busbar system includes a current busbar and a fluid dispenser. The current busbar is configured to connect at least one electronic device, and includes a first electrode, a second electrode, a partition, a first fluid channel, and a second fluid channel. The partition is disposed between the first electrode and the second electrode. The first fluid channel is adjacent to the first electrode. The second fluid channel is adjacent to the second electrode. The second fluid channel communicates with the first fluid channel. The fluid dispenser is connected to the first fluid channel.

### CROSS REFERENCE TO RELATED APPLICATIONS

The present application claims priority of U.S. Provisional Patent Applications No. 63/631,630, filed on Apr. 9, 2024, and Taiwan Patent Application No. 113122437, filed on Jun. 18, 2024, which are incorporated by reference herein in their entirety.

### BACKGROUND OF THE INVENTION

### Field of the Invention

The application relates in general to a current busbar system, and in particular, to a current busbar system connected to a fluid dispenser.

### Description of the Related Art

Thanks to the rapid development of computer technology and the internet, the computing and processing capability and power of electronic apparatuses is increasingly becoming higher. At the same time, the temperature generated by the operation of said electronic apparatuses has also increased.

A current busbar is an important tool for connecting one electronic apparatus to another. However, the high operating temperatures described above may cause the proper operation of a current busbar to fail. Therefore, how to address this problem has become an important issue.

### BRIEF SUMMARY OF INVENTION

To address the deficiencies of conventional products, an embodiment of the invention provides a busbar system, including a current busbar and a fluid dispenser. The current busbar is configured to connect at least one electronic device, and includes a first electrode, a second electrode, a partition, a first fluid channel, and a second fluid channel. The partition is disposed between the first electrode and the second electrode. The first fluid channel is adjacent to the first electrode, the second fluid channel is adjacent to the second electrode, and the second fluid channel communicates with the first fluid channel. The fluid dispenser is connected to the first fluid channel.

In some embodiments, the current busbar includes a first insulation member and a second insulation member. The first insulation member is disposed between the first fluid channel and the first electrode, and the second insulation member is disposed between the second fluid channel and the second electrode.

In some embodiments, the current busbar comprises a first tube and a second tube, the first fluid channel is formed in the first tube, and the second fluid channel is formed in the second tube.

In some embodiments, the first insulation member is disposed between the first tube and the first electrode and is in contact with the first tube and the first electrode, and the second insulation member is disposed between the second tube and the second electrode and is in contact with the second tube and the second electrode.

In some embodiments, each of the first insulation member and the second insulation member has a sheet structure.

In some embodiments, the first tube has a first outer surface facing the first electrode, and the first insulation member is a coating layer coated on the first outer surface, wherein the second tube has a second outer surface facing the second electrode, and the second insulation member is a coating layer coated on the second outer surface.

In some embodiments, the first insulation member surrounds the first fluid channel, and the first electrode surrounds the first insulation member, wherein the second insulation member surrounds the second fluid channel, and the second electrode surrounds the second insulation member.

In some embodiments, each of the first insulation member and the second insulation member comprises material with high electrical resistance and low thermal resistance.

In some embodiments, the thermal conductivity of each of the first insulation member and the second insulation member is within a range of 1.1 W/mK to 1.8 W/mK.

In some embodiments, the fluid dispenser is configured to provide a cooling fluid to the first fluid channel and the second fluid channel.

### BRIEF DESCRIPTION OF DRAWINGS

The invention can be more fully understood by reading the subsequent detailed description and examples with references made to the accompanying drawings, wherein:

FIG. 1 is a schematic diagram of a current busbar system according to an embodiment of the invention;

FIG. 2 is a cross-sectional view of a current busbar according to an embodiment of the invention;

FIG. 3 is a schematic diagram of a current busbar according to another embodiment of the invention;

FIG. 4 is a schematic diagram of a current busbar according to another embodiment of the invention; and

FIG. 5 is a schematic diagram of a current busbar system according to another embodiment of the invention.

### DETAILED DESCRIPTION OF INVENTION

The making and using of the embodiments of the current busbar system are discussed in detail below. It should be appreciated, however, that the embodiments provide many applicable inventive concepts that can be embodied in a wide variety of specific contexts. The specific embodiments discussed are merely illustrative of specific ways to make and use the embodiments, and do not limit the scope of the disclosure.

Unless defined otherwise, all technical and scientific terms used herein have the same meaning as commonly understood by one of ordinary skill in the art to which this invention belongs. It should be appreciated that each term, which is defined in a commonly used dictionary, should be interpreted as having a meaning conforming to the relative skills and the background or the context of the present disclosure, and should not be interpreted in an idealized or overly formal manner unless defined otherwise.

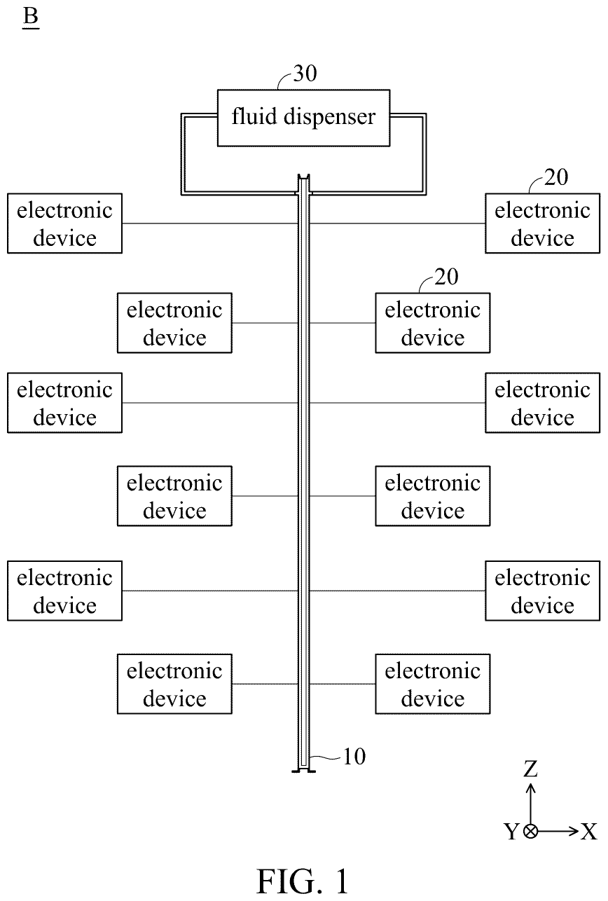

Referring to FIG. 1, a current busbar system B according to an embodiment of the invention includes a current busbar 10, one or more electronic devices 20, and a fluid dispenser 30. The electronic device 20 is electrically connected to the current busbar 10, and a connecting plug of an external electronic device can be detachably connected to the current busbar 10. Thus, the electronic device 20 can be connected to the external electronic device via the current busbar 10. The electronic device 20 can include a storage member or a calculating member, but it is not limited thereto. For example, the storage member can include solid-state drive (such as M.2 solid-state drive, mSATA solid-state drive, PCI-E solid-state drive, or IDE solid-state drive) and/or a memory (such as a read only memory (ROM), a flash memory, or a random access memory (RAM)), and the calculating member can include a central processing unit (CPU), a graphics processing unit (GPU), and/or a chipset.

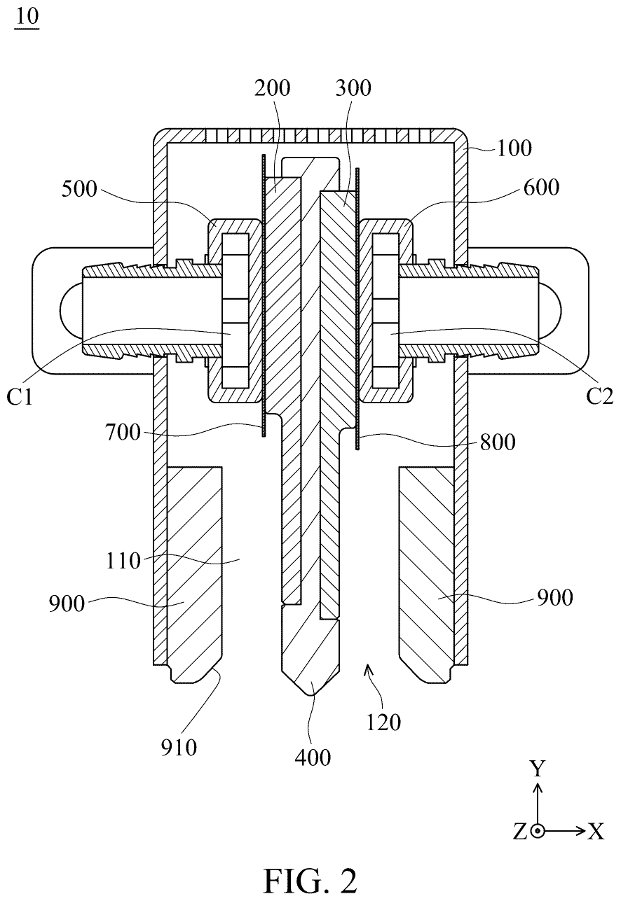

FIG. 2 is a cross-sectional view of the current busbar 10. As shown in FIG. 1 and FIG. 2, in this embodiment, the current busbar 10 primarily includes a housing 100, a first electrode 200, a second electrode 300, a partition 400, a first tube 500, a second tube 600, a first insulation member 700, a second insulation member 800, and at least one guiding member 900.

The housing 100 includes an inner space 110, and the first electrode 200, the second electrode 300, the partition 400, the first tube 500, the second tube 600, the first insulation member 700, and the second insulation member 800 are accommodated in the inner space 110. Therefore, the housing 100 can surround the first electrode 200, the second electrode 300, the partition 400, the first tube 500, the second tube 600, the first insulation member 700, and the second insulation member 800 to prevent them from being broken due to the impact of the external component.

Moreover, the housing 100 can further include an opening 120 that communicates with the inner space 110 and the external environment. Therefore, when the user wants to connect the external electronic device to the current busbar 10, a connecting plug of the external electronic device can pass through the opening 120 of the housing 100 to enter the inner space 110 and connect the first electrode 200 and the second electrode 300 in the inner space 110.

The first electrode 200 and the second electrode 300 can be an anode and a cathode respectively, and they can be electrically connected to the electronic device 20 of the current busbar system B. The partition 400 is affixed to the housing 100 and disposed between the first electrode 200 the second electrode 300. Therefore, the first electrode 200 the second electrode 300 can be separated, and the short circuit between the first electrode 200 the second electrode 300 can be prevented. For example, the partition 400 can include plastic, but it is not limited thereto.

The first tube 500 is adjacent to the first electrode 200, and a first fluid channel C1 can be formed in the inner of the first tube 500. Similarly, the second tube 600 is adjacent to the second electrode 300, and a second fluid channel C2 can be formed in the inner of the second tube 600. The first fluid channel C1 and the second fluid channel C2 communicate with each other, and the fluid dispenser 30 is connected to the first fluid channel C1 and the second fluid channel C2 at the top of the current busbar 10.

The fluid dispenser 30 can provide a cooling fluid to the first fluid channel C1. The cooling fluid can pass through the first fluid channel C1 and the second fluid channel C2 in sequence, and then flow back to the fluid dispenser 30. The heat of the first electrode 200 can be transferred to the cooling fluid through the wall of the first tube 500 when the cooling fluid passes through the first fluid channel C1, and the heat of the second electrode 300 can be transferred to the cooling fluid through the wall of the second tube 600 when the cooling fluid passes through the second fluid channel C2. Therefore, the cooling fluid can bring out the heat of the first electrode 200 and the second electrode 300, and the current intensity that can be withstood by the current busbar 10 can be increased. The signal transmission efficiency of the current busbar 10 can be enhanced accordingly.

After the cooling fluid flows back to the fluid dispenser 30, the fluid dispenser 30 can reduce the temperature of the cooling fluid, and provide the cooling fluid with the reduced temperature to the first fluid channel C1 again. For example, the fluid dispenser 30 can include an evaporator, a condenser, and/or a pump, but it is not limited thereto. In some embodiments, the fluid dispenser 30 is merely connected to the first fluid channel C1, and the second fluid channel C2 is connected to a fluid recycling device (such as a wastewater treatment equipment or a liquid storage tank). The fluid dispenser 30 can provide the cooling fluid to the first fluid channel C1 and the second fluid channel C2, and the cooling fluid flowing out of the second fluid channel C2 can directly enter the fluid recycling device. The cooling fluid can include water, oil, and/or other suitable cooling liquid.

The first insulation member 700 is disposed between the first electrode 200 and the first tube 500 and is in contact with the first electrode 200 and the first tube 500, so as to avoid the failure of the current busbar 10 that is caused by the cooling fluid or the liquid drop of condensing contacts the first electrode 200. The first insulation member 700 can have a sheet structure, and can include material with high electrical resistance and low thermal resistance. Therefore, the heat from the first electrode 200 can be rapidly transferred to the cooling fluid in the first tube 500.

For example, in this embodiment, the thickness of the first insulation member 700 can be ranged between 0.005 mm to 0.010 mm (such as 0.006 mm), and the thermal conductivity of the first insulation member 700 can be ranged between 1.1 W/mK to 1.8 W/mK (such as 1.3 W/mK).

The second insulation member 800 is disposed between the second electrode 300 and the second tube 600 and is in contact with the second electrode 300 and the second tube 600, so as to avoid the failure of the current busbar 10 that is caused by the cooling fluid or the liquid drop of condensing contacts the second electrode 300. The second insulation member 800 can have a sheet structure, and can include material with high electrical resistance and low thermal resistance. Therefore, the heat from the second electrode 300 can be rapidly transferred to the cooling fluid in the second tube 600.

For example, in this embodiment, the thickness of the second insulation member 800 can be ranged between 0.005 mm to 0.010 mm (such as 0.006 mm), and the thermal conductivity of the second insulation member 800 can be ranged between 1.1 W/mK to 1.8 W/mK (such as 1.3 W/mK).

The guiding member 900 can be affixed to the housing 100 and situated at the opening 120 of the housing 100. The guiding member 900 can include an inclined surface 910 to guide the connecting plug of the external electronic device to enter the inner space 110 of the housing 100. In some embodiments, the guiding member 900 and the housing 100 can be integrally formed as one piece.

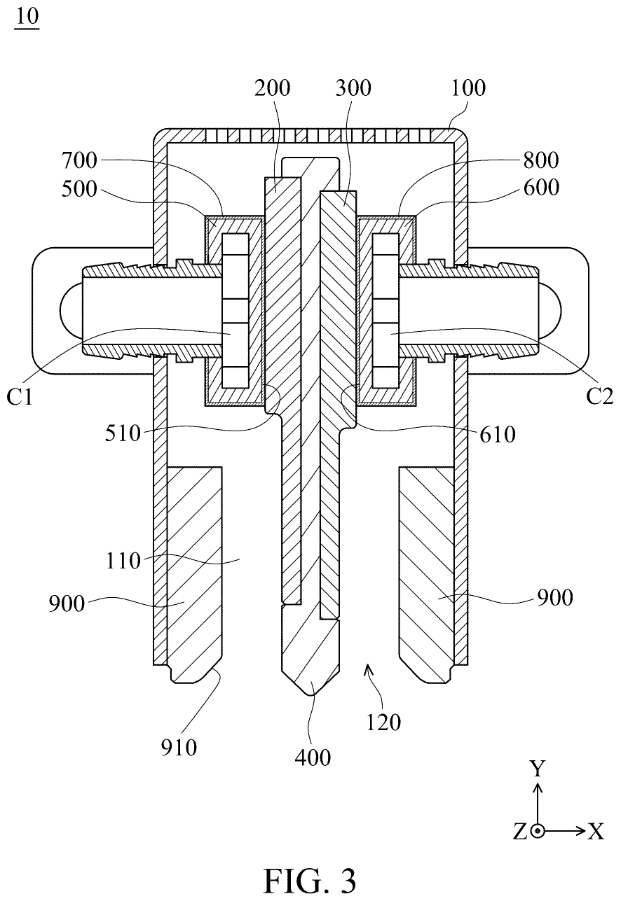

Referring to FIG. 3, in another embodiment of the invention, a current busbar 10 includes a housing 100, a first electrode 200, a second electrode 300, a partition 400, a first tube 500, a second tube 600, a first insulation member 700, a second insulation member 800, and at least one guiding member 900. The housing 100, the first electrode 200, the second electrode 300, the partition 400, the first tube 500, the second tube 600, and the guiding member 900 in this embodiment are the same as that in the embodiment shown in FIG. 1 and FIG. 2, so that the features thereof are not repeated in the interest of brevity.

In this embodiment, the first insulation member 700 is a coating layer, and it is at least coated on a first outer surface 510 of the first tube 500 facing the first electrode 200. The remaining outer surface of the first tube 500 can be also coated with the first insulation member 700 to increase the reliability of the current busbar 10. For example, the first insulation member 700 can surround the whole periphery of the first tube 500.

The first insulation member 700 can include material with high electrical resistance and low thermal resistance, and its thermal conductivity can be ranged between 1.1 W/mK to 1.8 W/mK (such as 1.6 W/mK), for example.

Similarly, the second insulation member 800 is a coating layer, and it is at least coated on a second outer surface 610 of the second tube 600 facing the second electrode 300. The remaining outer surface of the second tube 600 can be also coated with the second insulation member 800 to increase the reliability of the current busbar 10. For example, the second insulation member 800 can surround the whole periphery of the second tube 600.

The second insulation member 800 can include material with high electrical resistance and low thermal resistance, and its thermal conductivity can be ranged between 1.1 W/mK to 1.8 W/mK (such as 1.6 W/mK), for example.

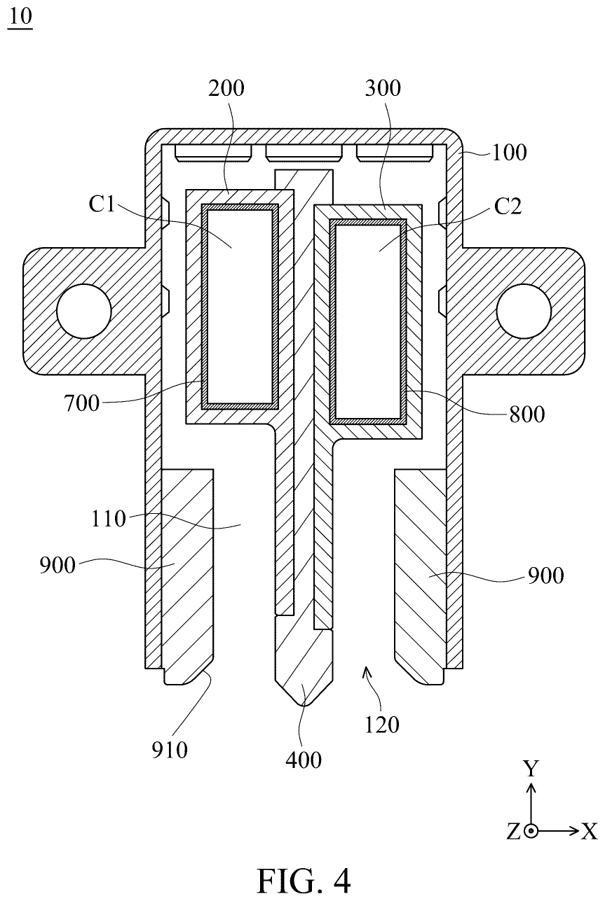

Referring to FIG. 4, in another embodiment of the invention, the first tube 500 and the second tube 600 are omitted, and each of the first electrode 200 and the second electrode 300 has an inner channel to form the first fluid channel C1 and the second fluid channel C2 respectively. The first insulation member 700 is attached on the wall surface of the inner channel of the first electrode 200, so as to avoid the failure of the current busbar 10 that is caused by the fluid contacts the first electrode 200. In other words, the first insulation member 700 surrounds the first fluid channel C1, and the first electrode 200 surrounds the first insulation member 700. The second insulation member 800 is attached on the wall surface of the inner channel of the second electrode 300, so as to avoid the failure of the current busbar 10 that is caused by the fluid contacts the second electrode 300. In other words, the second insulation member 800 surrounds the second fluid channel C2, and the second electrode 300 surrounds the second insulation member 800.

It should be noted that, in this embodiment, the first fluid channel C1 and the second fluid channel C2 may communicate with each other at the bottom of the current busbar 10 by using an insulation tube. Alternatively, in some embodiments, at least one hole penetrating the first electrode 200, the partition 400, and the second electrode 300 can be formed. An insulation member can be attached on the inner wall surface of the hole, so that the first fluid channel C1 and the second fluid channel C2 may communicate with each other while the short circuit of the first electrode 200 and the second electrode 300 can be avoided.

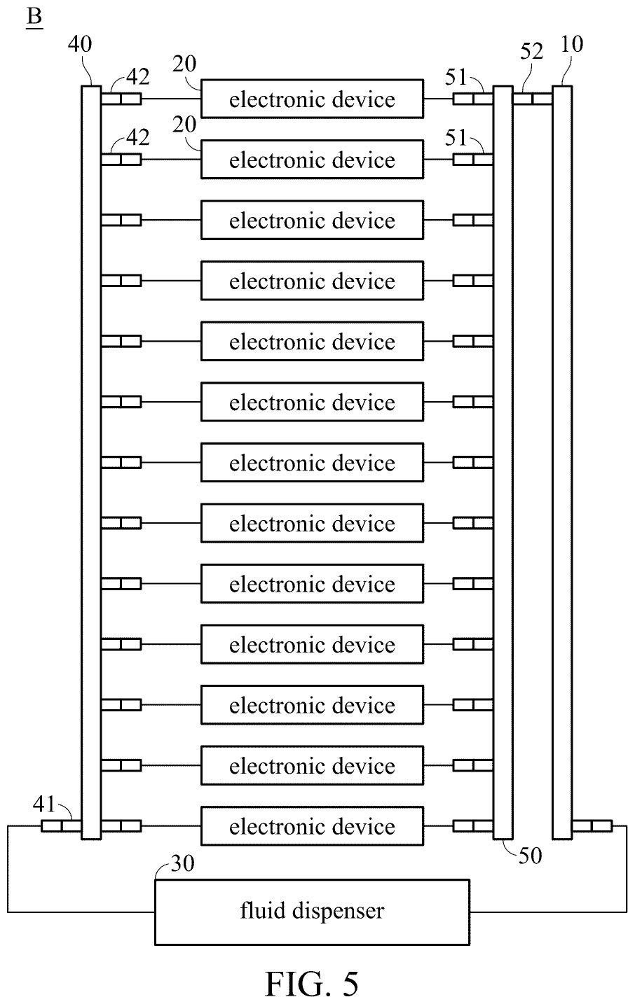

FIG. 5 is a current busbar system B according to another embodiment of the invention. In this embodiment, the current busbar system B includes a current busbar 10, one or more electronic devices 20, a fluid dispenser 30, a first manifold 40, and a second manifold 50, wherein the structure of the current busbar 10 can be the same as any one of the current busbar 10 shown in FIG. 2 to FIG. 4, so that the features thereof are not repeated in the interest of brevity.

The first manifold 40 includes a first input 41 and at least one first output 42. The first input 41 is coupled with the fluid dispenser 30, and the first output 42 is couple with the electronic device 20. The second manifold 50 includes at least one second input 51 and a second output 52. The second input 51 is coupled with the electronic device 20, and the second output 52 is couple with the current busbar 10. In particular, the second output 52 of the second manifold 50 is coupled to the first fluid channel C1 of the current busbar 10.

The second fluid channel C2 of the current busbar 10 is coupled to the fluid dispenser 30. Therefore, when the current busbar system B is operated, the fluid dispenser 30 can firstly provide the cooling fluid to the first manifold 40. The cooling fluid can flow through the electronic device 20 via the first output 42 of the first manifold 40 to bring out the heat of the electronic device 20. Subsequently, the cooling fluid can enter the second manifold 50 via the second input 51, and enter the current busbar 10 via the second output 52. When the cooling fluid flows through the first fluid channel C1 and the second fluid channel C2 and enters the fluid dispenser 30 again, it can bring out the heat of the first electrode 200 and the second electrode 300 of the current busbar 10.

In this embodiment, the first output 41 is situated at the bottom of the first manifold 40, the second output 52 is situated at the top of the second manifold 50, and the first fluid channel C1 and the second fluid channel C2 of the current busbar 10 are connected to the second manifold 50 and the fluid dispenser 30 at the top and bottom of the current busbar 10 respectively, but it is not limited thereto. The first manifold 40 can evenly distribute the fluid to the electronic device to reduce the temperature of the electronic device, and the temperature of the fluid flowing through the electronic device is significantly lower than the temperature of the current busbar 10. Therefore, since the fluid flowing through the electronic device is reused to reduce the temperature the current busbar, the overheating of the current busbar 10 can be prevented, and the power is saved relative to the traditional air-cooling method.

In summary, an embodiment of the invention provides a

[symbol]

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, compositions of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. Moreover, the scope of the appended claims should be accorded the broadest interpretation so as to encompass all such modifications and similar arrangements.

While the invention has been described by way of example and in terms of preferred embodiment, it should be understood that the invention is not limited thereto. On the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A current busbar system, comprising:
a current busbar, configured to connect at least one electronic device, wherein the current busbar comprises:
a first electrode;
a second electrode;
a partition, disposed between the first electrode and the second electrode;
a first fluid channel, adjacent to the first electrode; and
a second fluid channel, adjacent to the second electrode and communicating with the first fluid channel; and
a fluid dispenser, connected to the first fluid channel.

2. The current busbar system as claimed in claim 1, wherein the current busbar comprises:
a first insulation member, disposed between the first fluid channel and the first electrode; and
a second insulation member, disposed between the second fluid channel and the second electrode.

3. The current busbar system as claimed in claim 2, wherein the current busbar comprises a first tube and a second tube, the first fluid channel is formed in the first tube, and the second fluid channel is formed in the second tube.

4. The current busbar system as claimed in claim 3, wherein the first insulation member is disposed between the first tube and the first electrode and is in contact with the first tube and the first electrode, and the second insulation member is disposed between the second tube and the second electrode and is in contact with the second tube and the second electrode.

5. The current busbar system as claimed in claim 4, wherein each of the first insulation member and the second insulation member has a sheet structure.

6. The current busbar system as claimed in claim 4, wherein the first tube has a first outer surface facing the first electrode, and the first insulation member is a coating layer coated on the first outer surface, wherein the second tube has a second outer surface facing the second electrode, and the second insulation member is a coating layer coated on the second outer surface.

7. The current busbar system as claimed in claim 2, wherein the first insulation member surrounds the first fluid channel, and the first electrode surrounds the first insulation member, wherein the second insulation member surrounds the second fluid channel, and the second electrode surrounds the second insulation member.

8. The current busbar system as claimed in claim 2, wherein each of the first insulation member and the second insulation member comprises material with high electrical resistance and low thermal resistance.

9. The current busbar system as claimed in claim 2, wherein a thermal conductivity of each of the first insulation member and the second insulation member is within a range of 1.1 W/mK to 1.8 W/mK.

10. The current busbar system as claimed in claim 1, wherein the fluid dispenser is configured to provide a cooling fluid to the first fluid channel and the second fluid channel.

11. A current busbar system, comprising:
a first manifold, having a first input and a first output;
a second manifold, having a second input and a second output;
an electronic device, coupled to the first output and the second input;
a current busbar, comprising a first fluid channel and a second fluid channel, wherein the first fluid channel is coupled to the second output; and
a fluid dispenser, coupled to the first input and the first fluid channel.

12. The current busbar system as claimed in claim 11, wherein the current busbar is coupled to the second output at a top of the current busbar.

13. The current busbar system as claimed in claim 11, wherein the current busbar is coupled to the fluid dispenser at a bottom of the current busbar.

14. The current busbar system as claimed in claim 11, wherein the fluid dispenser is configured to provide a cooling fluid to enter the first manifold through the first input, the cooling fluid flows through the first output, the electronic device, the second input, the second output, the first fluid channel, and the second fluid channel in sequence, and then flows back to the fluid dispenser.

15. The current busbar system as claimed in claim 11, wherein the current busbar comprises:
a first electrode;
a second electrode;
a partition, disposed between the first electrode and the second electrode;
a first insulation member, disposed between the first fluid channel and the first electrode; and
a second insulation member, disposed between the second fluid channel and the second electrode.

16. The current busbar system as claimed in claim 15, wherein the current busbar comprises a first tube and a second tube, the first fluid channel is formed in the first tube, and the second fluid channel is formed in the second tube.

17. The current busbar system as claimed in claim 16, wherein the first insulation member is disposed between the first tube and the first electrode and is in contact with the first tube and the first electrode, and the second insulation member is disposed between the second tube and the second electrode and is in contact with the second tube and the second electrode.

18. The current busbar system as claimed in claim 17, wherein each of the first insulation member and the second insulation member has a sheet structure.

19. The current busbar system as claimed in claim 16, wherein the first tube has a first outer surface facing the first electrode, and the first insulation member is a coating layer coated on the first outer surface, wherein the second tube has a second outer surface facing the second electrode, and the second insulation member is a coating layer coated on the second outer surface.

20. The current busbar system as claimed in claim 15, wherein the first insulation member surrounds the first fluid channel, and the first electrode surrounds the first insulation member, wherein the second insulation member surrounds the second fluid channel, and the second electrode surrounds the second insulation member.
